(19) United States
(12) Patent Application Publication
(10) Pub. No.: US 2024/0360359 A1
(43) Pub. Date: Oct. 31, 2024

(54) COMPOSITION

(71) Applicant: Merck Patent GmbH, Darmstadt (DE)

(72) Inventors: Elizaveta KOSSOY, Jerusalem (IL); Ravit YAKOBI, Jerusalem (IL); Yaron AVIV, Jerusalem (IL); Suzanna AZOUBEL, Jerusalem (IL)

(21) Appl. No.: 18/684,382

(22) PCT Filed: Aug. 17, 2022
(86) PCT No.: PCT/EP2022/072886

§ 371 Date: Feb. 16, 2024

(30) Foreign Application Priority Data
Aug. 20, 2021 (EP) 21192340.4

(51) Int. Cl. C09K 11/06; C09D 11/322; H10K 59/38; H10K 85/10

(52) U.S. Cl. CPC C09K 11/06; C09D 11/322; H10K 59/38; H10K 85/141; C09K 2211/14

(57) ABSTRACT

The present invention relates to a composition comprising at least one light emitting moiety.

### FIELD OF THE INVENTION

The present invention relates to a composition comprising at least one light emitting moiety, process for fabricating a composition, use of a composition, a layer, process for fabricating a layer, a color conversion device and an optical device containing at least one color conversion device.

### BACKGROUND ART

WO 2017/054898 A1 describes a composition comprising red emission type nanocrystals, wetting and dispersing agent, propylene glycol monomethyl ether acetate as a solvent, an acryl polymer mixture including an acrylic unit including an acid group and a silane modified acrylic unit.

WO 2019/002239 A1 discloses a composition comprising a semiconducting light emitting nanoparticles, a polymer and a (meth)acrylate such as 1.4. cyclohexanedimethanol-monoacrylate having high viscosity around 90 cp.

### Patent Literature

1. WO 2017/054898 A1
2. WO 2019/002239 A1

### SUMMARY OF THE INVENTION

However, the inventors newly have found that there are still one or more of considerable problems for which improvement is desired, as listed below: realizing an improved homogeneous dispersion of light emitting moieties in the composition, improved homogeneous dispersion of scattering particles in the composition, preferably improved homogeneous dispersion of light emitting particles and scattering particles both in the composition, more preferably improved homogeneous dispersion of light emitting moieties and/or scattering particles without solvent; composition having lower viscosity suitable for inkjet printing, preferably a composition which can keep lower viscosity even if it is mixed with high loading of light emitting moieties and/or scattering particles, even more preferably without solvent; providing a composition having lower vapor pressure for large area uniform printing; providing a new composition realizing no or reduced residue around ink jet printing nozzle during/after ink jet printing, realizing improved QY and/or EQE of light emitting moieties in the composition, improved QY and/or EQE of light emitting moieties after printing; improved thermal stability; easy printing without clogging at a printing nozzle; easy handling of the composition, improved printing properties; simple fabrication process; improved absorbance of blue light; improved solidity of a layer made from the composition after inkjet printing; reducing/preventing excess of radicals in the composition during photo induced polymerization and reducing/preventing oxidation damage of the light emitting moiety; controlling a polymerization; realizing improved optical performance (e.g. higher EQE value of the cured composition film) after curing the composition either at low UV intensity (e.g. UV curing at 2.3 mW/cm²) or at high UV light intensity (e.g. UV curing 10 sec at 300 mW/cm²), preferably realizing improved optical performance (e.g. higher EQE of the cured composition film) after curing the composition at high UV light intensity (e.g. UV curing 10 sec at 300 mW/cm²) and/or improved film layer condition preferably realizing these at the same time; improved film brightness after polymerization of the composition at high UV light intensity and long term durability of the cured film.

The inventors aimed to solve one or more of the above-mentioned problems.

Then it is found a novel composition, preferably it is being of a photocurable composition, comprising at least, essentially consisting of, or consisting of;
i) a reactive monomer, preferably said monomer having one or more of functional groups, more preferably it is a (meth)acrylate monomer;
ii) a light emitting moiety;
iii) an antioxidant; and
iv) a polymerization initiator, and optionally v) one or more of scattering particles, preferably one or more of scattering particles are present and the total amount of said scattering particles based on the total amount of the solid content of the composition is in the range from 0.1 wt % to 99 wt %, more preferably it is in the range from 1 wt % to 20 wt %, even more preferably it is from 2 wt % to 10 wt %.

In another aspect, the present invention relates to a process for fabricating the composition of the present invention comprising at least the following step Y1;
Y1) mixing at least one light emitting moiety, a reactive monomer, an antioxidant and a polymerization initiator to form the composition.

In another aspect, the present invention relates to use of the composition of the present invention, in an electronic device, optical device, sensing device or in a biomedical device or for fabricating an electronic device, sensing device, optical device or a biomedical device.

In another aspect, the present invention relates to a layer containing a composition of the present invention.

In another aspect, the present invention relates to a layer containing at least, essentially consisting of or consisting of;
I) a (meth)acrylate polymer, preferably it is obtained or obtainable from the reactive monomers and the polymerization initiator in the composition of the present invention;
ii) a light emitting moiety;
iii) an antioxidant; and

optionally v) one or more of scattering particles, preferably one or more of scattering particles are present and the total amount of said scattering particles based on the total amount of the solid content of the composition is in the range from 0.1 wt % to 99 wt %, more preferably it is in the range from 1 wt % to 20 wt %, even more preferably it is from 2 wt % to 10 wt %.

In another aspect, the present invention relates to a process of fabricating the layer of the present invention, wherein the process comprises at least, essentially consisting of or consisting of the following steps;
I) providing a composition of the present invention onto a substrate, preferably
II) curing the composition, preferably said curing is performed by photo irradiation and/or thermal treatment.

In another aspect, the present invention relates to a layer obtained or obtainable from the process.

In another aspect, the present invention further relates to a color conversion device (100) comprising at least, essentially consisting of or consisting of, a 1^{st} pixel (161) partly or fully filled with the layer of the present invention, comprising at least a matrix material (120) containing a light emitting moiety (110), and a bank (150) comprising at least a polymer material, preferably the color conversion device (100) further contains a supporting medium (170).

In another aspect, the present invention further relates to use of the composition of the present invention for fabricating the layer of the present invention or the device (100) of the present invention.

In another aspect, the present invention furthermore relates to an optical device (300) containing at least one functional medium (320, 420, 520) configured to modulate a light or configured to emit light, and the color conversion device (100) of the present invention.

Further advantages of the present invention will become evident from the following detailed description.

### Definition of the Terms

In the present specification, symbols, units, abbreviations, and terms have the following meanings unless otherwise specified.

In the present specification, unless otherwise specifically mentioned, the singular form includes the plural form and “one” or “that” means “at least one”. In the present specification, unless otherwise specifically mentioned, an element of a concept can be expressed by a plurality of species, and when the amount (for example, mass % or mol %) is described, it means sum of the plurality of species. “and/or” includes a combination of all elements and also includes single use of the element.

In the present specification, when a numerical range is indicated using “to” or “-”, it includes both endpoints and units thereof are common. For example, 5 to 25 mol % means 5 mol % or more and 25 mol % or less.

In the present specification, the hydrocarbon means one including carbon and hydrogen, and optionally including oxygen or nitrogen. The hydrocarbyl group means a monovalent or divalent or higher valent hydrocarbon. In the present specification, the aliphatic hydrocarbon means a linear, branched or cyclic aliphatic hydrocarbon, and the aliphatic hydrocarbon group means a monovalent or divalent or higher valent aliphatic hydrocarbon. The aromatic hydrocarbon means a hydrocarbon comprising an aromatic ring which may optionally not only comprise an aliphatic hydrocarbon group as a substituent but also be condensed with an alicycle. The aromatic hydrocarbon group means a monovalent or divalent or higher valent aromatic hydrocarbon. Further, the aromatic ring means a hydrocarbon comprising a conjugated unsaturated ring structure, and the alicycle means a hydrocarbon having a ring structure but comprising no conjugated unsaturated ring structure.

In the present specification, the alkyl means a group obtained by removing any one hydrogen from a linear or branched, saturated hydrocarbon and includes a linear alkyl and branched alkyl, and the cycloalkyl means a group obtained by removing one hydrogen from a saturated hydrocarbon comprising a cyclic structure and optionally includes a linear or branched alkyl in the cyclic structure as a side chain.

In the present specification, the aryl means a group obtained by removing any one hydrogen from an aromatic hydrocarbon. The alkylene means a group obtained by removing any two hydrogens from a linear or branched, saturated hydrocarbon. The arylene means a hydrocarbon group obtained by removing any two hydrogens from an aromatic hydrocarbon.

In the present specification, when polymer has a plural types of repeating units, these repeating units copolymerize. These copolymerization are any of alternating copolymerization, random copolymerization, block copolymerization, graft copolymerization, or a mixture of any of these.

According to the present invention, the term “(meth)acrylate polymer” means a methacrylate polymer, an acrylate polymer or a combination of methacrylate polymer and an acrylate polymer.

The term “emission” means the emission of electromagnetic waves by electron transitions in atoms and molecules.

In the present specification, Celsius is used as the temperature unit. For example, 20 degrees means 20 degrees Celsius.

### DETAILED DESCRIPTION OF THE INVENTION

According to the present invention, in one aspect, the composition comprises at least, essentially consisting of or consisting of;
i) a reactive monomer, preferably said monomer having one or more of functional groups, more preferably it is a (meth)acrylate monomer;
ii) a light emitting moiety;
iii) an antioxidant; and
iv) a polymerization initiator, and optionally v) one or more of scattering particles, preferably one or more of scattering particles are present and the total amount of said scattering particles based on the total amount of the solid content of the composition is in the range from 0.1 wt % to 99 wt %, more preferably it is in the range from 1 wt % to 20 wt %, even more preferably it is from 2 wt % to 10 wt %.
   iii) An Antioxidant

According to the present invention, the composition comprises an antioxidant. In a preferred embodiment of the present invention, the total amount of said antioxidant based on the total amount of the solid content of the composition is more than 1 wt %, preferably it is in the range from 1.1 wt % to 10 wt %, more preferably it is from 1.2 wt % to 5 wt %, even more preferably it is from 1.3 wt % to 3 wt. % from the viewpoint of reducing/preventing excess of radicals in the composition during photo induced polymerization and/or reducing/preventing oxidation damage of the light emitting moiety.

In a preferred embodiment of the present invention, said antioxidant is selected from one or more members of the group consisting of hindered amines (e.g. tetramethyl piperidine and derivatives), phenol derivatives (e.g. MEHQ and its derivatives), quinone derivatives, thiols and unsaturated alkyls with conjugated double bonds (e.g. retinol and its derivatives), preferably it is a phenol derivatives, more preferably it is a hindered phenol type antioxidant from the viewpoint of effectively reducing/preventing excess of radicals in the composition during photo induced polymerization, reducing/preventing oxidation damage of the light emitting moiety and/or good compatibility to the composition (especially good compatibility to the reactive monomer, the light emitting moiety and the polymerization initiator).

It is also believed that by controlling the amount of the antioxidant as indicated above, the number of radicals (here “excess radicals) can be reduced/prevented. And it enables to control a polymerization condition (e.g., polymerization speed) and it leads improved optical performance (e.g., higher EQE of the cured composition film) after curing the composition of the present invention at high UV light intensity (e.g., UV curing 10 sec at 300 mW/cm²) and/or improved film layer condition.

iv) a polymerization initiator.

According to the present invention, the composition comprises a polymerization initiator. In a preferred embodiment of the present invention, the total amount of said polymerization initiator based on the total amount of the solid content of the composition is less than 1 wt % and above 0 wt. %, preferably it is in the range from 0.9 wt. % to 0.01 wt. %, more preferably it is from 0.8 to 0.05 wt %, even more preferably it is from 0.7 to 0.1 wt % from the viewpoint of controlling a polymerization, realizing improved optical performance (e.g. higher EQE of the cured composition film) after curing the composition of the present invention at high UV light intensity (e.g. UV curing 10 sec at 300 mW/cm²) and/or improved film layer condition.

In a preferred embodiment of the present invention, said polymerization initiator is selected from one or more members of the group consisting of Diphenyl(2,4,6-trimethylbenzoyl) phosphine oxide, Ethyl(2,4,6-trimethylbenzoyl)phenylphosphinate, Bis(2,4,6-Trimethylbenzoyl)phenylphosphine oxide, 4,4′-Bis(dimethylamino)benzophenone, 4,4′-Bis(diethylamino)benzophenone, 4-(Dimethylamino)benzophenone, Diphenyl (2,4,6 trimethylbenzoyl) phosphine oxide, 2-Hydroxy-2-methylpropiophenone, thioxanthen-9-one, Camphorquinone, 1-Phenyl-1,2-propanedione, carbazoles such as 9-vinylcarbazole, 1,2-Octanedione 1-[4-(phenylthio)phenyl]-2 (o-benzoyloxime), Ethanone 1-[9-ethyl-6-(2-methylbenzoyl)-9H-carbaaol-3-yl]-1-(O-acetyloxime), oxime esters, preferably it is selected from Bis(2,4,6-trimethylbenzoyl)-phenylphosphineoxide, Diphenyl(2,4,6-trimethylbenzoyl) phosphine oxide, Ethyl(2,4,6-trimethylbenzoyl) phenylphosphinate, a mixture of Bis(2,4,6-Trimethylbenzoyl)phenylphosphine oxide and Ethyl(2,4,6-trimethylbenzoyl) phenylphosphinate, and a combination of thereof, more preferably it is Bis(2,4,6-trimethylbenzoyl)-phenylphosphineoxide from the viewpoint of controlling a polymerization and/or realizing improved optical performance (e.g. higher EQE of the cured composition film) after curing the composition of the present invention at high UV light intensity (e.g. UV curing 10 sec at 300 mW/cm²), improved film layer condition and/or good compatibility to the composition (especially good compatibility to the reactive monomer, the light emitting moiety and the antioxidant).

### The Ratio of Antioxidant/Polymerization Initiator

In a preferred embodiment of the present invention, the mass ratio of the total amount of the antioxidant to the total amount of the polymerization initiator is more than 1 and 100 or less, preferably it is in the range from 1.1 to 50, more preferably from 1.2 to 30, even more preferably from 1.5 to 6.

It is believed that the above mentioned preferred range may lead significant technical effects: reducing/preventing excess of radicals in the composition during photo induced polymerization and reducing/preventing oxidation damage of the light emitting moiety; and controlling a polymerization and/or realizing improved optical performance (e.g. higher EQE of the cured composition film) after curing the composition of the present invention at high UV light intensity (e.g. UV curing 10 sec at 300 mW/cm²), and/or improved film layer condition at the same time. In other words, it is believed that it may lead improved film brightness after polymerization of the composition at high UV light intensity and long term durability of the cured film.

It is believed by adjusting the ratio of antioxidant/polymerization initiator it enables to more preferably control the polymerization condition of the composition (e.g., polymerization speed) and it leads improved optical performance (e.g., higher EQE of the cured composition film) after curing the composition of the present invention at high UV light intensity (e.g., UV curing 10 sec at 300 mW/cm²) and/or improved film layer condition.

### i) Reactive Monomer

It is believed that the lower viscosity is important to make a low viscosity composition suitable for inkjet printing. Therefore, a (meth)acrylate monomer having the viscosity value 35 cP or less at room temperature, preferably in the range from 1 to 35 cP, more preferably from 2 to 30 cP, even more preferably from 2 to 25 cP is especially suitable to make a composition for inkjet printing. By using these (meth)acrylate monomer in a composition, when it is mixed with another material such as semiconducting light emitting nanoparticles with high loading, the composition can still keep lower viscosity within the range suitable for inkjet printing.

In a preferred embodiment of the present invention, the boiling point (B.P.) of said reactive monomer is 80° C. or more, preferably it is in the range from 80° C. to 350° C., even more preferably from 85° C. to 200° C., furthermore preferably from 100° C. to 150° C. for large area uniform inkjet printing.

Here, the term “(meth)acrylate” is a general term for an acrylate and a methacrylate. Therefore, according to the present invention, the term “(meth)acrylate monomer” means a methacrylate monomer and/or an acrylate monomer.

According to the present invention, said B.P can be estimate by the known method such as like described in Science of Petroleum, Vol. II. p. 1281 (1398).

According to the present invention, any types of publicly available acrylates and/or methacrylates represented by chemical formula (I) or (II) can be used preferably.

Especially for the first aspect, any types of publicly available acrylates and/or methacrylates having the viscosity value of 25 cP or less at 25° C. represented by chemical formula (I), (II) and/or (III) can be used preferably.

Thus, according to the present invention, the reactive monomer of the composition is preferably a (meth)acrylate monomer selected from a mono-(meth)acrylate monomer, a di-(meth)acrylate monomer or a tri-(meth)acrylate monomer more preferably it is a di-methacrylate monomer or a di-acrylate monomer, tri-methacrylate monomer, tri-acrylate monomer, even more preferably it is represented by following chemical formula (II);

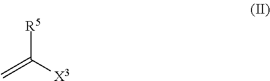

X³ is a non-substituted or substituted alkyl group, aryl group or an alkoxy group;
preferably the symbol X³ is

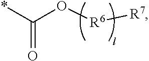

where “*” on the left side of the formula represents the connecting point to the end group C≡CR⁵ of the formula (I);
I is 0 or 1;
R⁵ is a hydrogen atom, halogen atom of Cl, Br, or F, methyl group, alkyl group, aryl group, alkoxy group, ester group, or a carboxylic acid group;
R⁶ is a straight alkylene chain or alkoxylene chain having 1 to 25 carbon atoms, preferably R⁶ is a straight alkylene chain or alkoxylene chain having 1 to 15 carbon atoms, more preferably 1 to 5 carbon atoms, which may be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═Se, C═NR^{a}, P(═O)(R^{a}), SO, SO2, NR^{a}, OS, or CONR^{a} and where one or more H atoms may be replaced by D, F, Cl, Br, I, CN or NO₂;
R⁷ is a straight alkylene chain or alkoxylene chain having 1 to 25 carbon atoms, preferably R⁷ is a straight alkylene chain or alkoxylene chain having 1 to 15 carbon atoms, more preferably 1 to 5 carbon atoms, which may be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═Se, C═NR^{a}, P(═O)(R^{a}), SO, SO2, NR^{a}, OS, or CONR^{a} and where one or more H atoms may be replaced by D, F, Cl, Br, I, CN or NO₂;

R^{a} is at each occurrence, identically or differently, H, D or an alkyl group having 1 to 20 carbon atoms, cyclic alkyl or alkoxy group having 3 to 40 carbon atoms, an aromatic ring system having 5 to 60 carbon ring atoms, or a hetero aromatic ring system having 5 to 60 carbon atoms, wherein H atoms may be replaced by D, F, Cl, Br, I; two or more adjacent substituents R^{a} here may also form a mono- or polycyclic, aliphatic, aromatic or heteroaromatic ring system with one another.

In a preferable embodiment, the composition further comprises a (meth)acrylate monomer represented by following chemical formula (I) and/or a (meth)acrylate monomer represented by following chemical formula (III);

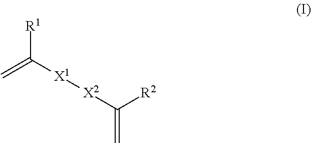

wherein
X¹ is a non-substituted or substituted alkyl group, aryl group or an alkoxy group or an ester group;
X² is a non-substituted or substituted alkyl group, aryl group or an alkoxy group or an ester group;
R¹ is a hydrogen atom, halogen atom of Cl, Br, or F, methyl group, alkyl group, aryl group, alkoxy group, ester group, or a carboxylic acid group;
R² is a hydrogen atom, halogen atom of Cl, Br, or F, methyl group, alkyl group, aryl group, alkoxy group, ester group, or a carboxylic acid group;
preferably the symbol X¹ is

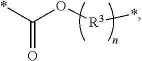

where “*” on the left side of the formula represents the connecting point to the carbon atom of the end group C═CR¹ of the formula (I) and “*” on the right side represents the connecting point to symbol X² of the formula (I);
n is 0 or 1;
preferably the symbol X² is

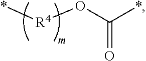

where “*” on the left side of the formula represents the connecting point to symbol X1 of the formula (I) and “*” on the right side represents the connecting point to the end group C═CR² of the formula (I);
m is 0 or 1;
preferably at least m or n is 1;
R³ is a straight alkylene chain or alkoxylene chain having 1 to 25 carbon atoms, a cycloalkane having 3 to 25 carbon atoms or an aryl group having 3 to 25 carbon atoms, preferably R³ is a straight alkylene chain or alkoxylene chain having 1 to 15 carbon atoms, more preferably 1 to 5 carbon atoms,
which may be substituted by one or more radicals R^{a}, where one or more non-adjacent CH₂ groups may be replaced by R^{a} C═CR^{a}, C≡C, Si(R^{a})₂, Ge(R^{a})₂, Sn(R^{a})₂, C═O, C═S, C═Se, C═NR^{a}, P(═O)(R^{a}), SO, SO2, NR^{a}, OS, or CONR^{a} and where one or more H atoms may be replaced by D, F, Cl, Br, I, CN or NO₂;
R⁴ is a straight alkylene chain or alkoxylene chain having 1 to 25 carbon atoms, a cycloalkane having 3 to 25 carbon atoms or an aryl group having 3 to 25 carbon atoms, preferably R⁴ is a straight alkylene chain or alkoxylene chain having 1 to 15 carbon atoms, more preferably 1 to 5 carbon atoms, which may be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═Se, C═NR^{a}, P(═O)(R^{a}), SO, SO2, NR^{a}, OS, or CONR^{a} and where one or more H atoms may be replaced by D, F, Cl, Br, I, CN or NO₂;
R^{a} is at each occurrence, identically or differently, H, D or an alkyl group having 1 to 20 carbon atoms, cyclic alkyl or alkoxy group having 3 to 40 carbon atoms, an aromatic ring system having 5 to 60 carbon ring atoms, or a hetero aromatic ring system having 5 to 60 carbon atoms, wherein H atoms may be replaced by D, F, Cl, Br, I; two or more adjacent substituents R^{a} here may also form a mono- or polycyclic, aliphatic, aromatic or heteroaromatic ring system with one another;

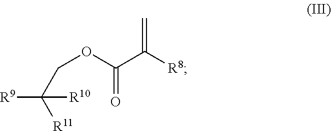

wherein R⁹ is hydrogen atom, a straight alkyl group having 1 to 25 carbon atoms or a (meth)acryl group represented by chemical formula (IV)

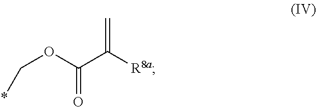

R¹⁰ is hydrogen atom, a straight alkyl group having 1 to 25 carbon atoms or a (meth)acryl group represented by chemical formula (V)

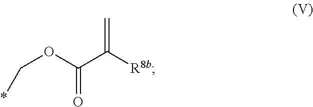

R¹¹ is hydrogen atom, a straight alkyl group having 1 to 25 carbon atoms or a (meth)acryl group represented by chemical formula (VI)

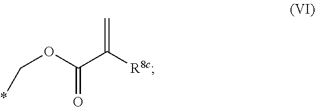

wherein R⁸, R^{8a}, R^{8b} and R^{8c} are, each independently or dependently of each other at each occurrence, H or CH₃;
wherein at least one of R⁹, R¹⁰ and R¹¹ is a (meth)acryl group, preferably two of R⁹, R¹⁰ and R¹¹ are a (meth)acryl group and other one is a hydrogen atom or a straight alkyl group having 1 to 25 carbon atoms, preferably the electric conductivity (S/cm) of the (meth)acrylate monomer of formula (III) is 1.0*10⁻¹⁰ or less, preferably it is 5.0*10⁻¹¹ or less, more preferably it is in the range from 5.0*10⁻¹¹ to 1.0*10⁻¹⁵, even more preferably it is in the range from 5.0*10⁻¹² to 1.0*10⁻¹⁵.

In a preferred embodiment of the present invention, the (meth)acrylate monomer of chemical formula (II) is in the composition and the mixing ratio of the (meth)acrylate monomer of chemical formula (I) to the (meth)acrylate monomer of chemical formula (II) is in the range from 1:99 to 99:1 (formula (I): formula (II)), preferably from 5:95 to 50:50, more preferably from 10:90 to 40:60, even more preferably it is from 15:85 to 35:65, preferably at least a purified (meth)acrylate monomer represented by chemical formula (I), (II) is used in the composition, more preferably the (meth)acrylate monomer of chemical formula (I) and the (meth)acrylate monomer of chemical formula (II) are both obtained or obtainable by a purification method.

In a preferred embodiment, the boiling point (B.P.) of said (meth)acrylate monomer of chemical formula (I) and/or chemical formula (II) is 80° C. or more, preferably it is in the range from 80° C. to 350° C., even more preferably from 85° C. to 200° C., furthermore preferably from 100° C. to 150° C. for large area uniform inkjet printing.

In a preferred embodiment of the present invention, the viscosity of the composition is 35 cP or less at room temperature, preferably in the range from 1 to 35 cP, more preferably from 2 to 30 cP, even more preferably from 2 to 25 cP.

According to the present invention, said viscosity can be measured by vibration type viscometer VM-10A (SEKONIC) at room temperature. https://www.sekonic.co.jp/english/product/viscometer/vm/vm_series.html

### (Meth)acrylate Monomer Represented by Chemical Formula (I) as a Matrix Material

Furthermore preferably, said R³ of formula (I) and R⁴ of formula (I) are, each independently of each other, selected from the following groups.

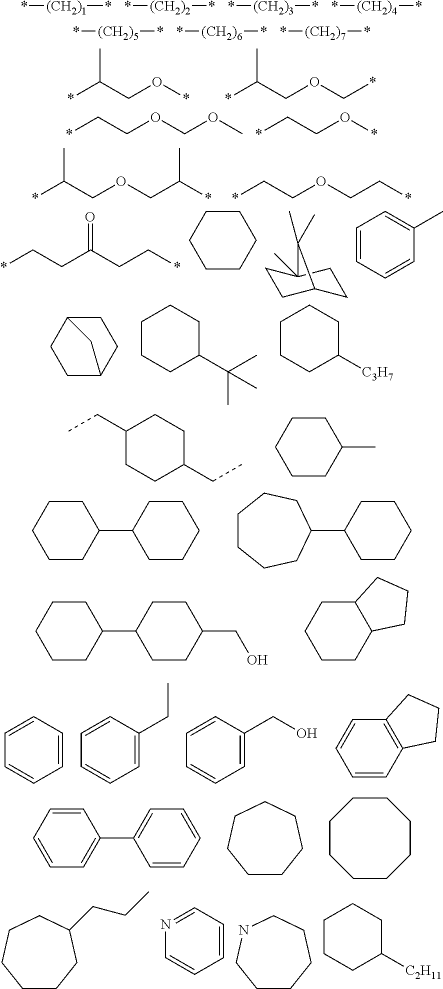

Particularly preferably, said R³ and R⁴ of formula (I) are, at each occurrence, independently or differently, selected from the following groups.

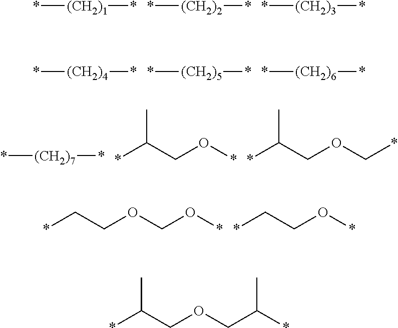

wherein “*” represents the connecting point to oxygen atom of the formula or the connecting point to X² of the formula in case of R³, and wherein “*” represents the connecting point to oxygen atom of the formula or the connecting point to X¹ of the formula in case of R⁴.

Furthermore preferably, said formula (I) is NDDA (nonanediol diacrylate; BP: 342° C.), HDDMA (hexanediol dimethacrylate; BP: 307), HDDA (hexanediol diacrylate; BP: 295° C.) or DPGDA (BP: 314° C.).

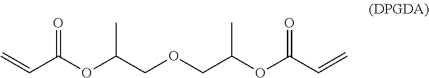 [SMILES: C=CC(=O)OC(C)COCC(C)OC(=O)C=C]

### (Meth)acrylate Monomer Represented by Chemical Formula (II)

It is believed that the (meth)acrylate monomer represented by following chemical formula (II) shows much lower viscosity value than the viscosity of the (meth)acrylate monomer of formula (I). Thus, by using the (meth)acrylate monomer represented by chemical formula (II) in combination of the (meth)acrylate monomer of chemical formula (I), a composition having much lower viscosity desirable for smooth inkjet printing can be realized, preferably without decreasing External Quantum Efficiency (EQE) value.

It is believed that said combination can realize a low viscosity composition comprising high amount of another materials, such as high loading of semiconducting light emitting nanoparticles. Thus, it is especially suitable for an inkjet printing when the composition comprises another material.

Furthermore preferably, said R⁷ of formula (II) is, at each occurrence, independently or differently, selected from the following groups, wherein the groups can be substituted with R^{a}, preferably they are unsubstituted by R^{a}.

| | | |
|---|---|---|
| *—(CH₂)₆—CH₃ | *—(CH₂)₇—CH₃ | *—(CH₂)₈—CH₃ |
| *—(CH₂)₉—CH₃ | *—(CH₂)₁₀—CH₃ | *—(CH₂)₁₁—CH₃ |
| *—(CH₂)₁₂—CH₃ | *—(CH₂)₄—OH | *—(CH₂)₂—OH |
| *—(CH₂)₆—OH | *—(CH₂)₃—OH | *—(CH₂)₅—OH |

wherein “*” represents the connecting point to R⁶ of X³ in case I is 1, and it is representing the connecting point to oxygen atom of X³ of the formula (II) in case n is 0.

The furthermore preferably, said formula (II) is Lauryl methacrylate (LM, viscosity 6 cP, BP: 142° C.) or Lauryl acrylate (LA, viscosity: 4.0 cP, BP: 313.2° C.).

It is believed that the higher amount of the (meth)acrylate monomer of chemical formula (II) to the total amount of the (meth)acrylate monomer of chemical formula (I) leads improved EQE of the composition, and the mixing weight ratio of the (meth)acrylate monomer of chemical formula (II) to the total amount of the (meth)acrylate monomer of chemical formula (I) less than 50 wt. % is preferable from the view point of viscosity of the composition, better ink-jetting properties of the composition.

Preferably, (meth)acrylate monomers purified by using silica column are used.

It is believed that an impurity removal from the (meth)acrylate monomers by the silica column purification leads improved QY of the semiconducting light emitting nanoparticle in the composition.

### (Meth)acrylate Monomer of Chemical Formula (III)

It is believed that the (meth)acrylate monomer of chemical formula (III) is useful to improve its solidity of a later made from the composition after inkjet printing.

According to the present invention, a publicly known a (meth)acrylate monomer represented by following chemical formula (III) can be used to improve solidity of a layer after inkjet printing and cross linking.

Very preferably, Trimethylolpropane Triacrylate (TMPTA) is used as the (meth)acrylate monomer of chemical formula (III).

In a preferable embodiment of the present invention, the amount of the (meth)acrylate monomer of chemical formula (III) based on the total amount of (meth)acrylate monomers in the composition is in the range from 0.001 wt. % to 25 wt. %, more preferably in the range from 0.1 wt. % to 15 wt. %, even more preferably from 1 wt. % to 10 wt. %,

Preferably, there (meth)acrylate monomers are purified by using silica column, are used.

It is believed that an impurity removal from the (meth)acrylate monomers by the silica column purification leads improved QY of the semiconducting light emitting nanoparticle in the composition.

According to the present invention, preferably the composition is configured to show the EQE value 20% or more, preferably 30% or more, even more preferably 33% or more and less than 95%, even more preferably 33% or more and less than 50%.

According to the present invention, said EQE is measured by the following EQE measurement process at room temperature which is based on using an integrating sphere, equipped with a 450 nm excitation light source coupled in via an optical fiber, and a spectrometer (Compass X, BWTEK), and which consists of a first measurement using air as the reference to detect the incident photons of the excitation light and a second measurement with the sample or test cell placed in front of the integrating sphere in between the opening of the integrating sphere and the exit of the optical fiber to detect the photons incident from the excitation light source transmitted through the sample and the photos emitted from the sample or test cell, whereas for both cases photons exiting the integrating sphere are counted by the spectrometer and EQE and BL calculation is done with the following equations and the number of photons of the excitation light and emission light is calculated by integration over the following wavelength ranges;

EQE=Photons [Emission light]/Photons [Excitation light measured without sample in place];

BL=Photons [−Excitation light measured with sample in place]/Photons [Excitation light measured without sample in place];
Emission light if green light emitting moieties are used: 490 nm-600 nm,
Emission light if red light emitting moieties are used: 580 nm-780 nm
Excitation light: 390 nm-490 nm.

### Light Emitting Moiety (110)

In a preferable embodiment of the present invention, said light emitting moiety is an organic and/or inorganic light emitting material, preferably it is an organic dye, inorganic phosphor and/or a semiconducting light emitting nanoparticle such as a quantum material.

In some embodiments of the present invention, the total amount of the light emitting moiety (110) is in the range from 0.1 wt. % to 99 wt. % based on the total amount of the solid content of the composition or based on the total amount of the 1st pixel (161), preferably from 10 wt. % to 80 wt. %, more preferably from 40 wt. % to 60 wt. %.

iii) Semiconducting Light Emitting Nanoparticle

According to the present invention, the term “semiconductor” means a material that has electrical conductivity to a degree between that of a conductor (such as copper) and that of an insulator (such as glass) at room temperature. Preferably, a semiconductor is a material whose electrical conductivity increases with the temperature.

The term “nanosized” means the size in between 0.1 nm to 150 nm, more preferably 3 nm to 50 nm.

Thus, according to the present invention, “semiconducting light emitting nanoparticle” is taken to mean that the light emitting material which size is in between 0.1 nm to 150 nm, more preferably 3 nm to 50 nm, having electrical conductivity to a degree between that of a conductor (such as copper) and that of an insulator (such as glass) at room temperature, preferably, a semiconductor is a material whose electrical conductivity increases with the temperature, and the size is in between 0.1 nm and 150 nm, preferably 0.5 nm to 150 nm, more preferably 1 nm to 50 nm.

According to the present invention, the term “size” means the average diameter of circle with an area equal to an average area of dark contrast features of the semiconducting nanosized light emitting particles in TEM image.

The average diameter of the semiconducting nanosized light emitting particles is calculated based on 100 semiconducting light emitting nanoparticles in a TEM image created by a Tecnai G2 Spirit Twin T-12 Transmission Electron Microscope.

In a preferred embodiment of the present invention, the semiconducting light emitting nanoparticle of the present invention is a quantum sized material.

According to the present invention, the term “quantum sized” means the size of the semiconducting material itself without ligands or another surface modification, which can show the quantum confinement effect, like described in, for example, ISBN: 978-3-662-44822-9.

For example, CdS, CdSe, CdTe, ZnS, ZnSe, ZnSeS, ZnTe, ZnO, GaAs, GaP, GaSb, HgS, HgSe, HgSe, HgTe, InAs, InP, InPZn, InPZnS, InPZnSe, InPZnSeS, InPZnGa, InPGaS, InPGaSe, InPGaSeS, InPZnGaSeS and InPGa, InCdP, InPCdS, InPCdSe, InSb, AlAs, AlP, AlSb, CuzS, CuzSe, CuInS2, CuInSe₂, Cu₂ (ZnSn) S₄, Cu₂ (InGa) S₄, TiO₂ alloys and a combination of any of these can be used.

According to the present invention, when said semiconducting light emitting nanoparticle may have a core-shell structure. In case said semiconducting light emitting nanoparticle does not have any shell layer, then the term “core” means semiconducting light emitting nanoparticle itself.

In a preferred embodiment of the present invention, the semiconducting material (hereafter “core” of the semiconducting light emitting nanoparticle”) comprises at least one element of the group 13 of the periodic table, and one element of the group 15 of the periodic table, preferably the element of the group 13 is In, and the element of the group 15 is P, more preferably the core is selected from the group consisting of InP, InPZn, InPZnS, InPZnSe, InPZnSeS, InPZnGa, InPGaS, InPGaSe, InPGaSeS, InPZnGaSeS and InPGa.

According to the present invention, a type of shape of the core of the semiconducting light emitting nanoparticle, and shape of the semiconducting light emitting nanoparticle to be synthesized are not particularly limited.

For examples, spherical shaped, elongated shaped, star shaped, polyhedron shaped, pyramidal shaped, tetrapod shaped, tetrahedron shaped, platelet shaped, cone shaped, and irregular shaped core and—or a semiconducting light emitting nanoparticle can be synthesized.

In some embodiments of the present invention, the average diameter of the core is in the range from 1.5 nm to 3.5 nm.

The average diameter of the core is calculated based on 100 semiconducting light emitting nanoparticles in a TEM image created by a Tecnai G2 Spirit Twin T-12 Transmission Electron Microscope by measuring the longest axis of each single particles.

In some embodiments of the present invention, at least one the shell layer comprises or a consisting of a 1^{st} element of group 12 of the periodic table and a 2^{nd} element of group 16 of the periodic table, preferably, the 1^{st} element is Zn, and the 2^{nd} element is S, Se, or Te; preferably a first shell layer covering directly onto said core comprises or a consisting of a 1^{st} element of group 12 of the periodic table and a 2^{nd} element of group 16 of the periodic table, preferably, the 1^{st} element is Zn, and the 2^{nd} element is S, Se, or Te.

In a preferred embodiment of the present invention, at least one shell layer (a first shell layer) is represented by following formula (XI), preferably the shell layer directly covering the core is represented by the chemical formula (XI);

ZnSₓSe_{y}Te_{z} (XI)
wherein 0≤x≤1, 0≤y≤1, 0≤z≤1, and x+y+z=1, preferably 0≤x≤1, 0≤y≤1, z=0, and x+y=1, preferably, the shell layer is ZnSe, ZnSₓSe_{y}, ZnSe_{y}Te_{z} or ZnSₓTe_{z}.

In some embodiments of the present invention, said shell layer is an alloyed shell layer or a graded shell layer, preferably said graded shell layer is ZnSₓSe_{y}, ZnSe_{y}Te_{z}, or ZnSₓTe_{z}, more preferably it is ZnSₓSe_{y}.

In some embodiments of the present invention, the semiconducting light emitting nanoparticle further comprises 2^{nd} shell layer onto said shell layer, preferably the 2^{nd} shell layer comprises or a consisting of a 3rd element of group 12 of the periodic table and a 4^{th} element of group 16 of the periodic table, more preferably the 3rd element is Zn, and the 4^{th} element is S, Se, or Te with the proviso that the 4^{th} element and the 2^{nd} element are not same.

In a preferred embodiment of the present invention, the 2^{nd} shell layer is represented by following formula (XI′),

ZnSₓSe_{y}Te_{z} (XI′)
wherein 0≤x≤1, 0≤y≤1, 0≤z≤1, and x+y+z=1, preferably, the shell layer is ZnSe, ZnSₓSe_{y}, ZnSe_{y}Te_{z}, or ZnSₓTe_{z} with the proviso that the shell layer and the 2^{nd} shell layer is not the same.

In some embodiments of the present invention, said 2^{nd} shell layer can be an alloyed shell layer.

In some embodiments of the present invention, the semiconducting light emitting nanoparticle can further comprise one or more additional shell layers onto the 2^{nd} shell layer as a multishell.

According to the present invention, the term “multishell” stands for the stacked shell layers consisting of three or more shell layers.

For examples, as a shell layer, CdS, CdZnS, CdS/ZnS, CdS, ZnS, ZnS/ZnSe, ZnSe/ZnS or combination of any of these can be used. Preferably, ZnS, ZnSe or ZnSe/ZnS.

For examples, as a semiconducting light emitting materials having core/shell structure, CdSe/CdS, CdSeS/CdZnS, CdSeS/CdS/ZnS, ZnSe/CdS, CdSe/ZnS, InP/ZnS, InP/ZnSe, InP/ZnSe/ZnS, InZnP/ZnS, InZnP/ZnSe, InZnP/ZnSe/ZnS, InGaP/ZnS, InGaP/ZnSe, InGaP/ZnSe/ZnS, InZnPS/ZnS, InZnPS/ZnSe, InZnPS/ZnSe/ZnS, ZnSe/CdS, ZnSe/ZnS or combination of any of these, can be used. Preferably, InP/ZnS, InP/ZnSe, InP/ZnSe/ZnS, InZnP/ZnS, InZnP/ZnSe, InZnP/ZnSe/ZnS, InGaP/ZnS, InGaP/ZnSe, InGaP/ZnSe/ZnS.

Such semiconducting light emitting nanoparticles are publicly available (for example from Sigma Aldrich) and/or can be synthesized with the method described for example in U.S. Pat. Nos. 7,588,828 B, 8,679,543 B and Chem. Mater. 2015, 27, pp 4893-4898.

In some embodiments of the present invention, the composition comprises two or more semiconducting light emitting nanoparticles.

In some embodiments of the present invention, the composition comprises a plurality of semiconducting light emitting nanoparticles.

In some embodiments of the present invention, the total amount of the semiconducting light emitting nanoparticles is in the range from 0.1 wt. % to 90 wt. % based on the total amount of the composition, preferably from 10 wt. % to 70 wt. %, more preferably from 30 wt. % to 50 wt. %.

### Ligands

In some embodiments of the present invention, optionally, the light emitting moiety can be directly over coated by one or more ligands, or the outer most surface of the inorganic part of the semiconducting light emitting nanoparticle can be directly coated by the ligands. As an option, ligand coated semiconducting light emitting nanoparticle can be overcoated by a polymer forming a polymer beads having said semiconducting light emitting nanoparticle(s) inside.

As the ligands, phosphines and phosphine oxides such as Trioctylphosphine oxide (TOPO), Trioctylphosphine (TOP), and Tributylphosphine (TBP); phosphonic acids such as Dodecylphosphonic acid (DDPA), Tridecylphosphonic acid (TDPA), Octadecylphosphonic acid (ODPA), and Hexylphosphonic acid (HPA); amines such as Oleylamine, Dodecyl amine (DDA), Tetradecyl amine (TDA), Hexadecyl amine (HDA), and Octadecyl amine (ODA), Oleylamine (OLA), 1-Octadecene (ODE), thiols such as hexadecane thiol and hexane thiol; mercapto carboxylic acids such as mercapto propionic acid and mercaptoundecanoic acid; carboxylic acids such as oleic acid, stearic acid, myristic acid; acetic acid, branched nonanoic acid, Polyethylenimine (PEI), monofunctional PEG thiol (mPEG-thiol) or a derivatives of mPEG thiol and a combination of any of these can be used.

Examples of such ligands have been described in, for example, the laid-open international patent application No. WO 2012/059931A.

### The Chemical Compound as an Additive

In a preferred embodiment of the present invention, the composition may further contain the chemical compound represented by following chemical formula (X^{A}).

Z(—X)u-Y (X^{A})

wherein
Z is *—R^{x1} or

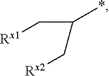

where “*” represents the connecting point to symbol Y of the formula, R^{x1} is a group selected from one or more members of the group consisting of phosphine group, phosphine oxide group, phosphate group, phosphonate group, thiol group, tertiary amine, carboxyl group, hetero cyclic group, silane group, sulfonic acid, hydroxyl group, phosphonic acid, preferably said group is a phosphonate group, thiol group, a carboxyl group or a combination of any of these, more preferably it is a carboxyl group or thiol group; and
R^{x2} is a group selected from one or more of members of the group consisting of phosphine group, phosphine oxide group, phosphate group, phosphonate group, thiol group, tertiary amine, carboxyl group, hetero cyclic group, silane group, sulfonic acid, hydroxyl group, phosphonic acid, preferably said group is a phosphonate group, thiol group, a carboxyl group or a combination of any of these, more preferably it is a carboxyl group or thiol group;
X is a single bond, an alkylene group having 1 to 15 carbon atoms, or an alkenylene group having 1 to 15 carbon atoms, or (poly)alkoxylene group having 1 to 15 carbon atoms, preferably Y is an (poly)alkoxylene group having 1 to 15 carbon atoms;
u is 0 or 1;
Y is a selected from unsaturated straight-chain alkyl group having carbon atoms 1 to 45, unsaturated or saturated branched chain alkyl group having carbon atoms 3 to 45, unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom; straight-chain alkenyl group having carbon atoms 2 to 45, branched chain alkenyl group having carbon atoms 3 to 45, unsaturated or saturated straight-chain or branched chain alkoxyl group having carbon atoms 1 to 45, unsaturated or saturated straight chain aryl-alkyl group having carbon atoms 4 to 45, unsaturated or saturated branched chain aryl-alkyl group having carbon atoms 6 to 45, straight-chain aryl-alkenyl group having carbon atoms 5 to 45, branched chain aryl-alkenyl group having carbon atoms 6 to 45, unsaturated or saturated straight-chain aryl-alkoxyl group having carbon atoms 5 to 45, unsaturated or saturated branched-chain aryl-alkoxyl group having carbon atoms 5 to 45, unsaturated or saturated cyclo-alkyl group having carbon atoms 4 to 45, cyclo-alkenyl group having carbon atoms 4 to 45, unsaturated or saturated cyclo-alkoxyl group having carbon atoms 4 to 45;
preferably said group is selected from unsaturated straight-chain alkyl group having carbon atoms 1 to 45, unsaturated or saturated branched chain alkyl group having carbon atoms 3 to 45, straight-chain alkenyl group having carbon atoms 2 to 45, branched chain alkenyl group having carbon atoms 3 to 45, unsaturated or saturated straight-chain or branched chain alkoxyl group having carbon atoms 1 to 45, unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
more preferably it is selected from unsaturated or saturated branched chain alkyl group having carbon atoms 3 to 45 or unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
preferably said carbon atoms of the alkyl group, the alkenyl group and/or the alkoxy group are in the range from 10 to 35, more preferably it is from 14 to 30,
furthermore preferably it is an unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom;
preferably said chain contains 1 to 5 carbon-carbon double bonds, more preferably 1 to 3 carbon-carbon double bonds, even more preferably 2 carbon-carbon double bonds,
said alkyl group, alkenyl group and/or alkoxy group, may optionally be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═Se, C═NR^{a}, P(═O)(R^{a}), SO, SO2, NR^{a}, OS, or CONR^{a} and where one or more H atoms may be replaced by D, F, Cl, Br, I, CN or NO₂, preferably Y is a straight-chain or branched alkyl group,
R^{a} is at each occurrence, identically or differently, H, D or an alkyl group having 1 to 20 carbon atoms, cyclic alkyl or alkoxy group having 3 to 40 carbon atoms, an aromatic ring system having 5 to 60 carbon ring atoms, or a hetero aromatic ring system having 5 to 60 carbon atoms, wherein H atoms may be replaced by D, F, Cl, Br, I; two or more adjacent substituents R^{a} here may also form a mono- or polycyclic, aliphatic, aromatic or heteroaromatic ring system with one another;

In case Y is an unsaturated or saturated straight-chain alkyl group having carbon atoms 1 to 80, preferably it is 8 to 70, more preferably 12 to 60, where one or more non-adjacent CH₂ groups is replaced by oxygen atom, C═O, C═S, C═Se, C═NH, SiH₂, SO, SO₂, OS, or CONH and where one or more H atoms may be replaced by D, F, Cl, Br, I, CN or NO₂, preferably one or more non-adjacent CH₂ groups is replaced by oxygen atom, preferably u is 1 and Y is represented by the following formula,

*—[CH(R¹)—CH(R²)-Q]ₓ-R³,
wherein R¹ is H or an alkyl group having carbon atoms 1 to 5, preferably said alkyl group is an methyl group; R² is H or an alkyl group having carbon atoms 1 to 5, preferably said alkyl group is an methyl group, Q is an oxygen atom, nitrogen atom or sulfur atom, preferably Q is an oxygen atom; R³ is H or a methyl group, x is an integer, preferably x is in the range from 1 to 300, more preferably from 2 to 200, even more preferably from 4 to 100, where “*” represents the connecting point to symbol X of the formula;
or

*—[(CHR¹)ₙ-Q)]ₓ-R³
wherein n is 2 or 3, Q is an oxygen atom, nitrogen atom or sulfur atom, preferably Q is an oxygen atom, R¹ is H or a methyl group, R³ is H or a methyl group, n is 1 to 5, preferably 1 to 3, more preferably n is 2, x is an integer, preferably x is in the range from 1 to 300, more preferably from 2 to 200, even more preferably from 4 to 100, where “*” represents the connecting point to symbol X of the formula,
and
preferably wherein Z represents an attaching group comprising one or two S atoms or Z is a carboxyl group, preferably Z is

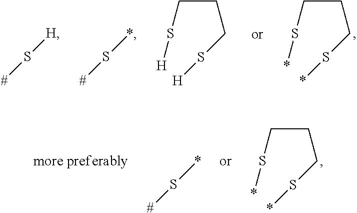

where “#” represents the connecting point to group X, and “*” represents the connecting point to the surface of the light emitting moiety.

It is believed that said weight ratio of the chemical compound is very preferable to control viscosity/solubility of the composition accordingly. And it is very preferable to prevent increasement of viscosity of the composition and/or keeping a good solubility of the light luminescent moieties in a long term storage in the composition.

As such a chemical compound, publicly known compounds satisfying the condition described above can be used preferably. For examples, mPEG-SH, elaidic acid, isostearic acid, linoleic acid can be used more preferably.

### Other Factors of the Composition

According to the present invention, in a preferred embodiment, the viscosity of the composition is 35 cP or less at room temperature, preferably in the range from 1 to 35 cP, more preferably from 2 to 30 cP, even more preferably from 2 to 25 cP.

In a preferred embodiment of the present invention, the composition comprises a solvent 10 wt % or less based on the total amount of the composition, more preferably it is 5 wt % or less, more preferably it is a solvent free composition, preferably the composition does not comprise any one of the following solvent selected from one or more members of the group consisting of ethylene glycol monoalkyl ethers, such as, ethylene glycol monomethyl ether, ethylene glycol monoethyl ether, ethylene glycol monopropyl ether, and ethylene glycol monobutyl ether; diethylene glycol dialkyl ethers, such as, diethylene glycol dimethyl ether, diethylene glycol diethyl ether, diethylene glycol dipropyl ether, and diethylene glycol dibutyl ether; propylene glycol monoalkyl ethers, such as, propylene glycol monomethyl ether (PGME), propylene glycol monoethyl ether, and propylene glycol monopropyl ether; ethylene glycol alkyl ether acetates, such as, methyl cellosolve acetate and ethyl cellosolve acetate; propylene glycol alkyl ether acetates, such as, propylene glycol monomethyl ether acetate (PGMEA), propylene glycol monoethyl ether acetate, and propylene glycol monopropyl ether acetate; ketones, such as, methyl ethyl ketone, acetone, methyl amyl ketone, methyl isobutyl ketone, and cyclohexanone; alcohols, such as, ethanol, propanol, butanol, hexanol, cyclo hexanol, ethylene glycol, triethylene glycol and glycerin; esters, such as, ethyl 3-ethoxypropionate, methyl 3-methoxypropionate and ethyl lactate; and cyclic asters, such as, gamma-butyro-lactone; chlorinated hydrocarbons, such as chloroform, dichloromethane, chlorobenzene, trimethyl benzenes such as 1,3,5-trimethylbenzene, 1,2,4-trimethyl benzene, 1,2,3-trimethyl benzene, docecylbenzene, cyclohexylbenzene, 1,2,3,4-tetramethylbenzene, 1,2,3,5-tetramethylbenzene, 3-isopropylbiphenyl, 3-methylbiphenyl, 4-methylbiphenyl and dichlorobenzene, preferably said solvent is propylene glycol alkyl ether acetates, alkyl acetates, ethylene glycol monoalkyl ethers, propylene glycol, and propylene glycol monoalkyl ethers.

It is believed that the less than 10 wt % of solvent in the composition leads improved ink-jetting and it can avoid 2^{nd} or more ink-jetting onto the same pixel after evaporation of the solvent.

According to the present invention, it is desirable not to add any solvent to realize large area inkjet printing with improved uniformity without causing any clogging at a nozzle and/or with good dispersity of semiconducting light emitting nanoparticles and/or with good dispersity of scattering particles.

According to the present invention, preferably the composition further comprises an another material selected from one or more members of the group consisting of;
iii) another light emitting moiety which is different from the light emitting moiety of the present invention, preferably said light emitting moiety comprises a ligand, more preferably said light emitting moiety comprises an alkyl type ligand having carbon atoms 2 to 25;
iv) a (meth)acrylate monomer different from the (meth)acrylate monomer of the present invention;
v) scattering particles, and
vi) optically transparent polymers, anti-oxidants, radical quenchers, photo initiators and/or surfactants.

In some embodiments of the present invention, preferably the composition of the present invention comprises
v) scattering particles; and
vii) at least one polymer configured so that said polymer enables to the scattering particles to disperse in the composition;
wherein the polymer comprises at least a phosphine group, phosphine oxide group, phosphate group, phosphonate group, thiol group, tertiary amine, carboxyl group, hetero cyclic group, silane group, sulfonic acid, hydroxyl group, phosphonic acid, or a combination of thereof, preferably the polymer comprises a tertiary amine, phosphine oxide group, phosphonic acid, or a phosphate group.

According to the present invention, the polymer configured so that said polymer enables to the scattering particles to disperse in the composition comprises at least a repeating unit A comprising a phosphine group, phosphine oxide group, phosphate group, phosphonate group, thiol group, tertiary amine, carboxyl group, hetero cyclic group, silane group, sulfonic acid, hydroxyl group, phosphonic acid, or a combination of thereof

In some embodiments of the present invention, the surface of the core, or the outermost surface of one or more shell layers of the semiconducting light emitting nanoparticle can be partly or fully over coated by the polymer. By using ligand exchange method, described in for example, Thomas Nann, Chem. Commun., 2005, 1735-1736, DOI: 10.1039/b-414807j, the polymer can be introduced onto the surface of the core or the outermost surface of the core of the semiconducting light emitting nanoparticle.

According to the present invention, in some embodiments, the content of said polymer is in the range from 1% to 500% by weight, more preferably in the range from 20% to 350% by weight, even more preferably from 50% to 200% by weight with respect to the total weight of the semiconducting light emitting nanoparticle.

In a preferred embodiment of the present invention, the weight average molecular weight (Mw) of the polymer is in the range from 200 g/mol to 30,000 g/mol, preferably from 250 g/mol to 2,000 g/mol, more preferably from 400 g/mol to 1,000 g/mol.

The molecular weight M_{w} is determined by means of GPC(=gel permeation chromatography) against an internal polystyrene standard.

As the polymer, commercially available wetting and dispersing additives which can be solved in non-polar and/or low polar organic solvent can be used preferably. Such as BYK-111, BYK-LPN6919, BYK-103, BYK-P104, BYK-163 ([trademark], from BYK com.), TERPLUS MD1000 series, such as MD1000, MD1100 ([trademark], from Otsuka Chemical), Poly(ethylene glycol) methyl ether amine (Sigma-Aldrich 767565 [trademark], from Sigma Aldrich), Polyester bis-MPA dendron, 32 hydroxyl, 1 thiol, (Sigma-Aldrich 767115 [trademark], from Sigma Aldrich), LIPONOL DA-T/25 (From Lion Specialty Chemicals Co.), Carboxymethyl cellulose (from Polyscience etc.), another wetting and dispersing additives disclosed in for examples, “Marc Thiry et. al., ACSNANO, American Chemical society, Vol. 5, No. 6, pp 4965-4973, 2011”, “Kimihiro Susumu, et. al., J. Am. Chem. Soc. 2011, 133, pp 9480-9496”.

Thus, in some embodiments of the present invention, the composition comprises at least the (meth)acrylate monomer of chemical formula (I), the (meth)acrylate monomer of chemical formula (II) and the polymer configured so that said polymer enables to the scattering particles to disperse in the composition, wherein the mixing ratio of the (meth)acrylate monomer of chemical formula (I): the (meth)acrylate monomer of chemical formula (II): the polymer is 10:89:1 to 50:40:10, preferably in the range from 15:82:3 to 30:60:10.

In some embodiments of the present invention, the composition comprises at least the (meth)acrylate monomer of chemical formula (III), the (meth)acrylate monomer of chemical formula (II) and the polymer configured so that said polymer enables to the scattering particles to disperse in the composition, wherein the mixing ratio of the (meth)acrylate monomer of chemical formula (III): the (meth)acrylate monomer of chemical formula (II): the polymer is 10:89:1 to 50:40:10, preferably in the range from 15:82:3 to 30:60:10.

In some embodiment of the present invention, a composition comprises, essentially consisting of or consisting of, at least a polymer derived or derivable from the (meth)acrylate monomers of the composition of the present invention.

In a preferred embodiment of the present invention, said polymer is derived or derivable from all the (meth)acrylate monomers in the composition, for example, at least the (meth)acrylate monomer of chemical formula (I) and/or the (meth)acrylate monomer of chemical formula (II).

### v) Scattering Particles

According to the present invention, as the scattering particles, publicly known small particles of inorganic oxides such as SiO₂, SnO₂, CuO, CoO, Al₂O₃, TiO₂, Fe₂O₃, Y₂O₃, ZnO, ZnS, MgO; organic particles such as polymerized polystyrene, polymerized PMMA; inorganic hollow oxides such as hollow silica or a combination of any of these; can be optionally used to further enhance scattering properties in the obtained film. The amount of the scattering particles is preferably 10 wt % or less based on the total amount of the solid contents of the layer, preferably it is in the range from 8 to 0 wt %, more preferably it is in the range from 6 to 0 wt %.

According to the present invention, as a transparent polymer, a wide variety of publicly known transparent polymers suitable for optical devices, described in for example, WO 2016/134820A can be used preferably.

According to the present invention, the term “transparent” means at least around 60% of incident light transmit at the thickness used in an optical medium and at a wavelength or a range of wavelength used during operation of an optical medium. Preferably, it is over 70%, more preferably, over 75%, the most preferably, it is over 80%.

According to the present invention the term “polymer” means a material having a repeating unit and having the weight average molecular weight (Mw) 1000 g/mol, or more.

The molecular weight Mw is determined by means of GPC(=gel permeation chromatography) against an internal polystyrene standard.

In some embodiments of the present invention, the glass transition temperature (Tg) of the transparent polymer is 70° C. or more and 250° C. or less.

Tg is measured based on changes in the heat capacity observed in Differential scanning colorimetry like described in Rickey J Seyler, Assignment of the Glass Transition, ASTM publication code number (PCN) 04-012490-50.

For example, as the transparent polymer for the transparent matrix material, poly(meth)acrylates, epoxys, polyurethanes, polysiloxanes, can be used preferably.

In a preferred embodiment of the present invention, the weight average molecular weight (Mw) of the polymer as the transparent matrix material is in the range from 1,000 to 300,000 g/mol, more preferably it is from 10,000 to 250,000 g/mol.

According to the present invention, publicly known anti-oxidants, radical quenchers, photo initiators and/or surfactants can be used preferably like described in WO 2016/134820A.

According to the present invention, in one aspect, a composition comprises a polymer derived or derivable from one or more of the reactive monomers of the composition of the present invention, an antioxidant and optionally one or more of scattering particles, preferably it is obtained or obtainable by curing the composition of the present invention.

### Use of the Composition

In another aspect, the present invention relates to use of the composition of the present invention, in an electronic device, optical device, sensing device or in a biomedical device or for fabricating an electronic device, sensing device, optical device or a biomedical device.

### A Layer Containing the Composition and a Process of Fabricating the Layer

In another aspect, the present invention relates to a layer containing the composition of the present invention.

In another aspect, the present invention relates to a process for fabricating the composition of the present invention comprising at least the following step Y1;
Y1) mixing at least one light emitting moiety, a reactive monomer, an antioxidant and a polymerization initiator to form the composition.

In another aspect, the present invention relates to a layer containing at least, essentially consisting of or consisting of;
I) a (meth)acrylate polymer, preferably it is obtained or obtainable from the preferably it is obtained or obtainable from the reactive monomers in the composition of the present invention;
II) a light emitting moiety; and
iii) an antioxidant; and
optionally v) one or more of scattering particles, preferably one or more of scattering particles are present and the total amount of said scattering particles based on the total amount of the solid content of the composition is in the range from 0.1 wt % to 99 wt %, more preferably it is in the range from 1 wt % to 20 wt %, even more preferably it is from 2 wt % to 10 wt %.

More details of the composition such as “reactive monomer”, “light emitting moiety” and “chemical compound” are described above such as in the section of “reactive monomer”, “light emitting moiety” and “chemical compound”.

Additional additives as described in the section of “additional material” can be mixed.

In a preferable embodiment, the layer thickness of the layer is in the range from 1 to 50 um, preferably from 5 to 30, more preferably from 8 to 20, furthermore preferably from 10 to 15 um.

In a preferable embodiment, the layer is configured to show the EQE value 25% or more, preferably 30% or more and less than 95%, even more preferably 33% or more and less than 50%.

In another aspect, the present invention relates to a process of fabricating the layer of the present invention, wherein the process comprises at least, essentially consisting of or consisting of the following steps;
I) providing a composition of the present invention onto a substrate, preferably
II) curing the composition, preferably said curing is performed by photo irradiation and/or thermal treatment.

In another aspect, the present invention relates to a layer obtained or obtainable from the process.

### Color Conversion Device (100)

A color conversion device (100) comprising at least a 1^{st} pixel (161) partly or fully filled with the layer of any one of claims 20 to 22 and 24 comprising at least a matrix material (120) containing a light emitting moiety (110), and a bank (150) comprising at least a polymer material, preferably the color conversion device (100) further contains a supporting medium (170).

### 1^{st} Pixel (161)

According to the present invention, said 1^{st} pixel (161) comprises at least a matrix material (120) containing a light emitting moiety (110). In a preferable embodiment, the 1^{st} pixel (161) is a solid layer obtained or obtainable by curing the composition of the present invention containing at least one acrylate monomer together with at least one light emitting moiety (110), preferably said curing is a photo curing by photo irradiation, thermal curing or a combination of a photo curing and a thermal curing.

In some embodiments of the present invention, the layer thickness of the pixel (161) is in the range from 0.1 to 100 μm, preferably it is from 1 to 50 μm, more preferably from 5 to 25 μm.

In some embodiments of the present invention, the color conversion device (100) further contains a 2^{nd} pixel (162), preferably the device (100) contains at least said 1^{st} pixel (161), 2^{nd} pixel (162) and a 3rd pixel (163), more preferably said 1^{st} pixel (161) is a red color pixel, the 2^{nd} pixel (162) is a green color pixel and the 3rd pixel (163) is a blue color pixel, even more preferably the 1^{st} pixel (161) contains a red light emitting moiety (110R), the 2^{nd} color pixel (162) contains a green light emitting moiety (110G) and the 3rd pixel (163) does not contain any light emitting moiety.

In some embodiments, at least one pixel (160) additionally comprises at least one light scattering particle (130) in the matrix material (120), preferably the pixel (160) contains a plurality of light scattering particles (130).

In some embodiments of the present invention, said 1^{st} pixel (161) consists of one pixel or two or more sub-pixels configured to emit red-color when irradiated by an excitation light, more preferably said sub-pixels contains the same light emitting moiety (110).

### Matrix Material (120)

In a preferable embodiment, the matrix material (120) contains a (meth)acrylate polymer, preferably it is a methacrylate polymer, an acrylate polymer or a combination of thereof, more preferably it is an acrylate polymer, even more preferably said matrix material (120) is obtained or obtainable from the composition of the present invention containing at least one acrylate monomer, further more preferably said matrix material (120) is obtained or obtainable from the composition of the present invention containing at least one di-acrylate monomer, particularly preferably said matrix material (120) is obtained or obtainable from the composition of the present invention containing at least one di-acrylate monomer and a mono-acrylate monomer, preferably said composition is a photosensitive composition.

### Bank (150)

In some embodiments of the present invention, the height of the bank (150) is in the range from 0.1 to 100 μm, preferably it is from 1 to 50 μm, more preferably from 1 to 25 μm, furthermore preferably from 5 to 20 μm.

In a preferred embodiment of the present invention, the bank (150) is configured to determine the area of said 1^{st} pixel (161) and at least a part of the bank (150) is directly contacting to at least a part of the 1^{st} pixel (161), preferably said 2^{nd} polymer of the bank (150) is directly contacting to at least a part of the 1^{st} polymer of the 1^{st} pixel (161).

More preferably, said bank (150) is photolithographically patterned and said 1^{st} pixel (161) is surrounded by the bank (150), preferably said 1^{st} pixel (161), the 2^{nd} pixel (162) and the 3rd pixel (163) are all surrounded by the photolithographically patterned bank (150).

In another aspect, the present invention further relates to a color conversion device (100) obtainable or obtained from the method of the present invention.

In another aspect, the present invention further relates to use of the color conversion device (100) of the present invention in an optical device (300) containing at least one functional medium (320, 420, 520) configured to modulate a light or configured to emit light.

Further, in another aspect, the present invention further relates to an optical device (300) containing at least one functional medium (320, 420, 520) configured to modulate a light or configured to emit light, and the color conversion device (100) of the present invention.

### Preferable Embodiments

1. A composition, preferably it is being of a photocurable composition, comprising, essentially consisting of, or consisting of, at least;
i) a reactive monomer, preferably said monomer having one or more of functional groups, more preferably it is a (meth)acrylate monomer;
ii) a light emitting moiety;
iii) an antioxidant; and
iv) a polymerization initiator, and optionally v) one or more of scattering particles, preferably one or more of scattering particles are present and the total amount of said scattering particles based on the total amount of the solid content of the composition is in the range from 0.1 wt % to 99 wt %, more preferably it is in the range from 1 wt % to 20 wt %, even more preferably it is from 2 wt % to 10 wt %.

2. The composition of embodiment 1, wherein the total amount of said antioxidant based on the total amount of the solid content of the composition is more than 1 wt %, preferably it is in the range from 1.1 wt % to 10 wt %, more preferably it is from 1.2 wt % to 5 wt %, even more preferably it is from 1.3 wt % to 3 wt. %.

3. The composition of embodiment 1 or 2, wherein the total amount of said polymerization initiator based on the total amount of the solid content of the composition is less than 1 wt % and above 0 wt. %, preferably it is in the range from 0.9 wt. % to 0.01 wt. %, more preferably it is from 0.8 to 0.05 wt %, even more preferably it is from 0.7 to 0.1 wt %.

4. The composition of any one of embodiments 1 to 3, wherein the ratio of the total amount of the antioxidant to the total amount of the polymerization initiator is more than 1 and 100 or less, preferably it is in the range from 1.1 to 50, more preferably from 1.2 to 30, even more preferably from 1.5 to 6.

5. The composition of any one of embodiments 1 to 4, wherein said antioxidant is selected from one or more members of the group consisting of hindered amines, preferably said hindered amine is tetramethyl piperidine or derivatives of the tetramethyl piperidine, phenol derivatives, preferably said phenol derivative is MEHQ (Hydroquinone Monomethyl Ether, 4-Hydroxyanisole, 4-Methoxyphenol) or a derivative of MEHQ, quinone derivatives, thiols and unsaturated alkyls with conjugated double bonds, preferably said unsaturated alkyls with conjugated double bond is retinol or a derivative of retinol.

6. The composition of any one of embodiments 1 to 5, wherein said polymerization initiator is selected from one or more members of the group consisting of Diphenyl(2,4,6-trimethylbenzoyl) phosphine oxide, Ethyl(2,4,6-trimethylbenzoyl)phenylphosphinate, Bis(2,4,6-Trimethylbenzoyl)phenylphosphine oxide, 4,4′-Bis(dimethylamino) benzophenone, 4,4′-Bis(diethylamino) benzophenone, 4-(Dimethylamino)benzophenone, Diphenyl (2,4,6 trimethylbenzoyl) phosphine oxide, 2-Hydroxy-2-methylpropiophenone, thioxanthen-9-one, Camphorquinone, 1-Phenyl-1,2-propanedione, carbazoles such as 9-vinylcarbazole, 1,2-Octanedione 1-[4-(phenylthio)phenyl]-2 (o-benzoyloxime), Ethanone 1-[9-ethyl-6-(2-methylbenzoyl)-9H-carbaaol-3-yl]-1-(O-acetyloxime), oxime esters, preferably it is selected from Bis(2,4,6-trimethylbenzoyl)-phenylphosphineoxide, Diphenyl(2,4,6-trimethylbenzoyl) phosphine oxide, Ethyl(2,4,6-trimethylbenzoyl) phenylphosphinate, a mixture of Bis(2,4,6-Trimethylbenzoyl)phenylphosphine oxide and Ethyl(2,4,6-trimethylbenzoyl) phenylphosphinate, and a combination of thereof, more preferably it is Bis(2,4,6-trimethylbenzoyl)-phenylphosphineoxide.

7. The composition of any one of embodiments 1 to 6, wherein the reactive monomer is a (meth)acrylate monomer selected from a mono-(meth)acrylate monomer, a di-(meth)acrylate monomer or a tri-(meth)acrylate monomer more preferably it is a di-methacrylate monomer or a di-acrylate monomer, tri-methacrylate monomer, tri-acrylate monomer, even more preferably it is represented by following chemical formula (II);

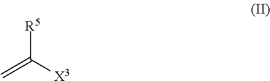

X³ is a non-substituted or substituted alkyl group, aryl group or an alkoxy group;
preferably the symbol X³ is

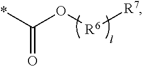

where “*” on the left side of the formula represents the connecting point to the end group C═CR⁵ of the formula (I);
I is 0 or 1;
R⁵ is a hydrogen atom, halogen atom of Cl, Br, or F, methyl group, alkyl group, aryl group, alkoxy group, ester group, or a carboxylic acid group;
R⁶ is a straight alkylene chain or alkoxylene chain having 1 to 25 carbon atoms, preferably R⁶ is a straight alkylene chain or alkoxylene chain having 1 to 15 carbon atoms, more preferably 1 to 5 carbon atoms, which may be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═Se, C═NR^{a}, P(═O)(R^{a}), SO, SO2, NR^{a}, OS, or CONR^{a} and where one or more H atoms may be replaced by D, F, Cl, Br, I, CN or NO₂;
R⁷ is a straight alkylene chain or alkoxylene chain having 1 to 25 carbon atoms, preferably R⁷ is a straight alkylene chain or alkoxylene chain having 1 to 15 carbon atoms, more preferably 1 to 5 carbon atoms, which may be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═Se, C═NR^{a}, P(═O)(R^{a}), SO, SO2, NR^{a}, OS, or CONR^{a} and where one or more H atoms may be replaced by D, F, Cl, Br, I, CN or NO₂;
R^{a} is at each occurrence, identically or differently, H, D or an alkyl group having 1 to 20 carbon atoms, cyclic alkyl or alkoxy group having 3 to 40 carbon atoms, an aromatic ring system having 5 to 60 carbon ring atoms, or a hetero aromatic ring system having 5 to 60 carbon atoms, wherein H atoms may be replaced by D, F, Cl, Br, I; two or more adjacent substituents R^{a} here may also form a mono- or polycyclic, aliphatic, aromatic or heteroaromatic ring system with one another.

8. The composition of any one of embodiments 1 to 7, further comprises a (meth)acrylate monomer represented by following chemical formula (I) and/or a (meth)acrylate monomer represented by following chemical formula (III);

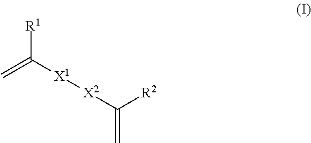

wherein
X¹ is a non-substituted or substituted alkyl group, aryl group or an alkoxy group or an ester group;
X² is a non-substituted or substituted alkyl group, aryl group or an alkoxy group or an ester group;
R¹ is a hydrogen atom, halogen atom of Cl, Br, or F, methyl group, alkyl group, aryl group, alkoxy group, ester group, or a carboxylic acid group;
R² is a hydrogen atom, halogen atom of Cl, Br, or F, methyl group, alkyl group, aryl group, alkoxy group, ester group, or a carboxylic acid group;
preferably the symbol X¹ is

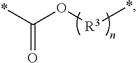

where “*” on the left side of the formula represents the connecting point to the carbon atom of the end group C═CR¹ of the formula (I) and “*” on the right side represents the connecting point to symbol X² of the formula (I);
n is 0 or 1;
preferably the symbol X² is

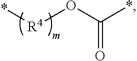

where “*” on the left side of the formula represents the connecting point to symbol X1 of the formula (I) and “*” on the right side represents the connecting point to the end group C═CR² of the formula (I);
m is 0 or 1;
preferably at least m or n is 1;
R³ is a straight alkylene chain or alkoxylene chain having 1 to 25 carbon atoms, a cycloalkane having 3 to 25 carbon atoms or an aryl group having 3 to 25 carbon atoms, preferably R³ is a straight alkylene chain or alkoxylene chain having 1 to 15 carbon atoms, more preferably 1 to 5 carbon atoms,
which may be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═Se, C═NR^{a}, P(═O)(R^{a}), SO, SO2, NR^{a}, OS, or CONR^{a} and where one or more H atoms may be replaced by D, F, Cl, Br, I, CN or NO₂;
R⁴ is a straight alkylene chain or alkoxylene chain having 1 to 25 carbon atoms, a cycloalkane having 3 to 25 carbon atoms or an aryl group having 3 to 25 carbon atoms, preferably R⁴ is a straight alkylene chain or alkoxylene chain having 1 to 15 carbon atoms, more preferably 1 to 5 carbon atoms,
which may be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═Se, C═NR^{a}, P(═O)(R^{a}), SO, SO2, NR^{a}, OS, or CONR^{a} and where one or more H atoms may be replaced by D, F, Cl, Br, I, CN or NO₂;
R^{a} is at each occurrence, identically or differently, H, D or an alkyl group having 1 to 20 carbon atoms, cyclic alkyl or alkoxy group having 3 to 40 carbon atoms, an aromatic ring system having 5 to 60 carbon ring atoms, or a hetero aromatic ring system having 5 to 60 carbon atoms, wherein H atoms may be replaced by D, F, Cl, Br, I; two or more adjacent substituents
R^{a} here may also form a mono- or polycyclic, aliphatic, aromatic or heteroaromatic ring system with one another;

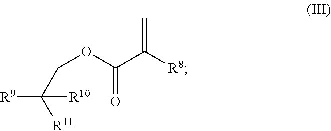

wherein R⁹ is hydrogen atom, a straight alkyl group having 1 to 25 carbon atoms or a (meth)acryl group represented by chemical formula (IV)

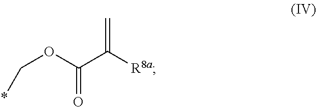

R¹⁰ is hydrogen atom, a straight alkyl group having 1 to 25 carbon atoms or a (meth)acryl group represented by chemical formula (V)

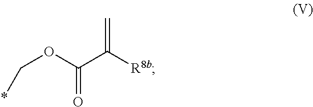

R¹¹ is hydrogen atom, a straight alkyl group having 1 to 25 carbon atoms or a (meth)acryl group represented by chemical formula (VI)

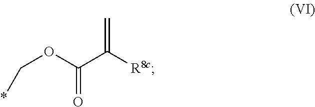

wherein R⁸, R^{8a}, R^{8b} and R^{8c} are, each independently or dependently of each other at each occurrence, H or CH₃;
wherein at least one of R⁹, R¹⁰ and R¹¹ is a (meth)acryl group, preferably two of R⁹, R¹⁰ and R¹¹ are a (meth)acryl group and other one is a hydrogen atom or a straight alkyl group having 1 to 25 carbon atoms, preferably the electric conductivity (S/cm) of the (meth)acrylate monomer of formula (III) is 1.0*10⁻¹⁰ or less, preferably it is 5.0*10⁻¹¹ or less, more preferably it is in the range from 5.0*10⁻¹¹ to 1.0*10⁻¹⁵, even more preferably it is in the range from 5.0*10⁻¹² to 1.0*10⁻¹⁵.

9. The composition of any one of embodiments 1 to 8, wherein the (meth)acrylate monomer of chemical formula (II) is in the composition and the mixing ratio of the (meth)acrylate monomer of chemical formula (I) to the (meth)acrylate monomer of chemical formula (II) is in the range from 1:99 to 99:1 (formula (I): formula (II)), preferably from 5:95 to 50:50, more preferably from 10:90 to 40:60, even more preferably it is from 15:85 to 35:65, preferably at least a purified (meth)acrylate monomer represented by chemical formula (I), (II) is used in the composition, more preferably the (meth)acrylate monomer of chemical formula (I) and the (meth)acrylate monomer of chemical formula (II) are both obtained or obtainable by a purification method.

10. The composition of any one of embodiments 1 to 9, wherein the boiling point (B.P.) of said (meth)acrylate monomer of chemical formula (I) and/or chemical formula (II) is 80° C. or more, preferably it is in the range from 80° C. to 350° C., even more preferably from 85° C. to 200° C., further more preferably from 100° C. to 150° C. for large area uniform inkjet printing.

11. The composition of any one of embodiments 1 to 10, wherein said light emitting moiety is an organic light emitting moiety and/or inorganic light emitting moiety, preferably it is an inorganic light emitting moiety, more preferably it is an inorganic light emitting moiety is an inorganic phosphor or a quantum material, preferably said light emitting moiety contains a ligand attached onto the outer most surface of the light emitting moiety, more preferably said ligand comprises at least one straight-chain or branched chain alkyl group having carbon atoms 1 to 45, straight-chain or branched chain alkenyl group having carbon atoms 1 to 45 or straight-chain or branched chain alkoxyl group having carbon atoms 1 to 45.

12. The composition of any one of embodiments 1 to 11, wherein the total amount of the light emitting moiety is in the range from 0.1 wt. % to 90 wt. % based on the total amount of the composition, preferably from 10 wt. % to 70 wt. %, more preferably from 15 wt. % to 50 wt. %. 13. The composition of any one of claims 1 to 12, wherein the viscosity of the composition is 35 cP or less at room temperature, preferably in the range from 1 to 35 cP, more preferably from 2 to 30 cP, even more preferably from 2 to 25 cP.

14. The composition of any one of embodiments 1 to 13, comprises an another material selected from one or more members of the group consisting of;
iii) another light emitting moiety which is different from the light emitting moiety of embodiment 1, preferably said light emitting moiety comprises a ligand, more preferably said light emitting moiety comprises an alkyl type ligand having carbon atoms 2 to 25;
iv) a (meth)acrylate monomer different from the (meth)acrylate monomer of embodiment 8;
v) scattering particles, and
vi) optically transparent polymers, a 2^{nd} anti-oxidant that is different from the anti-oxidant of embodiment 1, radical quenchers, a 2^{nd} photo initiator that is different from the photo initiator of embodiment 1 and/or surfactants.

15. The composition of any one of embodiments 1 to 14, comprises
v) scattering particles; and
vii) at least one polymer configured so that said polymer enables to the scattering particles to be dispersed in the composition;
wherein the polymer comprises at least a phosphine group, phosphine oxide group, phosphate group, phosphonate group, thiol group, tertiary amine, carboxyl group, hetero cyclic group, silane group, sulfonic acid, hydroxyl group, phosphonic acid, or a combination of thereof, preferably the polymer comprises a tertiary amine, phosphine oxide group, phosphonic acid, or a phosphate group.

16. The composition of any one of embodiments 1 to 15, the composition is configured to show the EQE value 20% or more, preferably 30% or more, even more preferably 33% or more and less than 95%, even more preferably 33% or more and less than 50%.

17. The composition of any one of embodiments 1 to 16, wherein the composition comprises a solvent 10 wt % or less based on the total amount of the composition, more preferably it is 5 wt % or less, more preferably it is a solvent free composition, preferably the composition does not comprise any one of the following solvent selected from one or more members of the group consisting of ethylene glycol monoalkyl ethers, such as, ethylene glycol monomethyl ether, ethylene glycol monoethyl ether, ethylene glycol monopropyl ether, and ethylene glycol monobutyl ether; diethylene glycol dialkyl ethers, such as, diethylene glycol dimethyl ether, diethylene glycol diethyl ether, diethylene glycol dipropyl ether, and diethylene glycol dibutyl ether; propylene glycol monoalkyl ethers, such as, propylene glycol monomethyl ether (PGME), propylene glycol monoethyl ether, and propylene glycol monopropyl ether; ethylene glycol alkyl ether acetates, such as, methyl cellosolve acetate and ethyl cellosolve acetate; propylene glycol alkyl ether acetates, such as, propylene glycol monomethyl ether acetate (PGMEA), propylene glycol monoethyl ether acetate, and propylene glycol monopropyl ether acetate; ketones, such as, methyl ethyl ketone, acetone, methyl amyl ketone, methyl isobutyl ketone, and cyclohexanone; alcohols, such as, ethanol, propanol, butanol, hexanol, cyclo hexanol, ethylene glycol, triethylene glycol and glycerin; esters, such as, ethyl 3-ethoxypropionate, methyl 3-methoxypropionate and ethyl lactate; and cyclic asters, such as, gamma-butyro-lactone; chlorinated hydrocarbons, such as chloroform, dichloromethane, chlorobenzene, trimethyl benzenes such as 1,3,5-trimethylbenzene, 1,2,4-trimethyl benzene, 1,2,3-trimethyl benzene, docecylbenzene, cyclohexylbenzene, 1,2,3,4-tetramethylbenzene, 1,2,3,5-tetramethylbenzene, 3-isopropylbiphenyl, 3-methylbiphenyl, 4-methylbiphenyl and dichlorobenzene, preferably said solvent is propylene glycol alkyl ether acetates, alkyl acetates, ethylene glycol monoalkyl ethers, propylene glycol, and propylene glycol monoalkyl ethers.

18. The composition of any one of embodiments 1 to 17, comprises at least the (meth)acrylate monomer of chemical formula (I), the (meth)acrylate monomer of chemical formula (II) and the polymer configured so that said polymer enables to the scattering particles to be dispersed in the composition, wherein the mixing ratio of the (meth)acrylate monomer of chemical formula (I): the (meth)acrylate monomer of chemical formula (II): the polymer is 10:89:1 to 50:40:10, preferably in the range from 15:82:3 to 30:60:10.

19. The composition of any one of embodiments 1 to 17, comprises at least the (meth)acrylate monomer of chemical formula (III), the (meth)acrylate monomer of chemical formula (II) and the polymer configured so that said polymer enables to the scattering particles to disperse in the composition, wherein the mixing ratio of the (meth)acrylate monomer of chemical formula (III): the (meth)acrylate monomer of chemical formula (II): the polymer is 10:89:1 to 50:40:10, preferably in the range from 15:82:3 to 30:60:10.

20. A composition comprising, essentially consisting of, or consisting of, a polymer derived or derivable from one or more of the reactive monomers of the composition of any one of embodiments 1 to 19, an antioxidant and optionally one or more of scattering particles, preferably it is obtained or obtainable by curing the composition of any one of embodiments 1 to 19.

21. Process for fabricating the composition of any one of embodiments 1 to 19 comprising, essentially consisting of, or consisting of, at least the following step Y1;
Y1) mixing at least one light emitting moiety, a reactive monomer, an antioxidant and a polymerization initiator to form the composition.

22. Use of the composition of any one of preceding embodiments, in an electronic device, optical device, sensing device or in a biomedical device or for fabricating an electronic device, sensing device, optical device or a biomedical device.

23. A layer containing, essentially consisting of, or consisting of, the composition of embodiment 20.

24. A layer containing, essentially consisting of, or consisting of, at least;
I) a (meth)acrylate polymer, preferably it is obtained or obtainable from the reactive monomers and the polymerization initiator in the composition of any one of embodiments 1 to 19;
ii) a light emitting moiety;
iii) an antioxidant; and
optionally v) one or more of scattering particles, preferably one or more of scattering particles are present and the total amount of said scattering particles based on the total amount of the solid content of the composition is
10 wt % or less based on the total amount of the solid contents of the layer, more preferably it is in the range from 8 to 0 wt %, even more preferably it is in the range from 6 to 0 wt %.

25. The layer of embodiment 23 or 24, wherein the layer thickness of the layer is in the range from 1 to 50 um, preferably 5 to 15, more preferably 8 to 15, furthermore preferably 8-12 um.

26. The layer of any one of embodiments 23 to 25, 27, wherein it is configured to show the EQE value 25% or more, preferably 30% or more and less than 95%, even more preferably 33% or more and less than 50%.

27. Process of fabricating the layer of any one of embodiments 23 to 26, wherein the process comprises at least the following steps;
I) providing a composition of any one of embodiments 1 to 19 onto a substrate,
II) curing the composition, preferably said curing is performed by photo irradiation and/or thermal treatment.

28. A layer obtained or obtainable from the process of embodiment 27.

29. A color conversion device (100) comprising, essentially consisting of, or consisting of, at least a 1^{st} pixel (161) partly or fully filled with the layer of any one of embodiments 23 to 26 and 28 comprising at least a matrix material (120) containing a light emitting moiety (110), and a bank (150) comprising at least a polymer material, preferably the color conversion device (100) further contains a supporting medium (170).

30. The device (100) of embodiment 29, wherein the height of the bank (150) is in the range from 0.1 to 100 μm, preferably it is from 1 to 50 μm, more preferably from 1 to 25 μm, furthermore preferably from 5 to 20 μm.

31. The device (100) of embodiment 29 or 30, wherein the layer thickness of the pixel (161) is in the range from 0.1 to 100 μm, preferably it is from 1 to 50 μm, more preferably from 5 to 25 μm.

32. Use of the composition of any one of embodiments 1 to 19 for fabricating the layer of any one of embodiments 23 to 26, 28 or the device (100) of any one of embodiments 29 to 301

33. An optical device (300) containing at least one functional medium (320, 420, 520) configured to modulate a light or configured to emit light, and the color conversion device (100) of any one of embodiments 29 to 31.

### Technical Effects of the Invention

The present invention provides one or more of the following technical effects: realizing an improved homogeneous dispersion of light emitting moieties in the composition, improved homogeneous dispersion of scattering particles in the composition, preferably improved homogeneous dispersion of light emitting particles and scattering particles both in the composition, more preferably improved homogeneous dispersion of light emitting moieties and/or scattering particles without solvent; composition having lower viscosity suitable for inkjet printing, preferably a composition which can keep lower viscosity even if it is mixed with high loading of light emitting moieties and/or scattering particles, even more preferably without solvent; providing a composition having lower vapor pressure for large area uniform printing; providing a new composition realizing no or reduced residue around ink jet printing nozzle during/after ink jet printing, realizing improved QY and/or EQE of light emitting moieties in the composition, improved QY and/or EQE of light emitting moieties after printing; improved thermal stability; easy printing without clogging at a printing nozzle; easy handling of the composition, improved printing properties; simple fabrication process; improved absorbance of blue light; improved solidity of a later made from the composition after inkjet printing; reducing/preventing excess of radicals in the composition during photo induced polymerization and reducing/preventing oxidation damage of the light emitting moiety; controlling a polymerization; realizing improved optical performance (e.g. higher EQE value of the cured composition film) after curing the composition either at low UV intensity (e.g. UV curing at 2.3 mW/cm²) or at high UV light intensity (e.g. UV curing 10 sec at 300 mW/cm²), preferably realizing improved optical performance (e.g. higher EQE of the cured composition film) after curing the composition at high UV light intensity (e.g. UV curing 10 sec at 300 mW/cm²) and/or improved film layer condition preferably realizing these at the same time; improved film brightness after polymerization of the composition at high UV light intensity and long term durability of the cured film.

The working examples below provide descriptions of the present invention, as well as an in-detail description of their fabrication. However, the present invention does not necessary to be limited to the working examples.

### Working Examples

LA: lauryl acrylate
HDDA: 1,6-hexanediol diacrylate
AO: Antioxidant
PI: Polymerization initiator
wt %: total amount in composition

### Preparation of TiO₂ Stock in Lauryl Acrylate (LA)

15.79 g of TiO₂ in n-octane is mixed with 38.00 g of LA in a glass flask and n-octane in the mixture is evaporated by rotary evaporator under vacuum at 40 deg. C. Thus obtained the 20 wt. % TiO₂ stock in LA.

### Comparative Example 1

Ink comprised of 45 wt % of InP based green QDs having ZnSe/ZnS double shell layers, 2.25 wt % of oleic acid, 1 wt % of Phenylbis(2,4,6-trimethylbenzoyl) phosphine oxide (Irga™ 819)., 0.5 wt % of Irganox™ 1010 and monomer mixture of LA:HDDA, when LA:HDDA ratio is by weight is 8:2.

### Working Example 1

Ink comprised of 45 wt % of InP based green QDs having ZnSe/ZnS double shell layers, 2.25 wt % of oleic acid, 0.1 wt % of Irga™ 819, 2 wt % of Irganox™ 1010 and monomer mixture of LA:HDDA, when LA:HDDA ratio is by weight is 8:2.

### Comparative Example 2

Ink comprised of 45 wt % of InP based green QDs having ZnSe/ZnS double shell layers, 2.25 wt % of oleic acid, 1 wt % of Irga™ 819, 0.5 wt % of Irganox™ 1010, 5 wt % TiO₂ and monomer mixture of LA:HDDA, when LA:HDDA ratio is by weight is 8:2.

### Working Example 2

Ink comprised of 45 wt % of InP based green QDs having ZnSe/ZnS double shell layers, 2.25 wt % of oleic acid, 0.1 wt % of Irga™ 819, 2 wt % of Irganox™ 1010, 5 wt % TiO₂ and monomer mixture of LA:HDDA, when LA:HDDA ratio is by weight is 8:2.

### Comparative Example 3

Ink comprised of 50 wt % of InP based green QDs having ZnSe/ZnS double shell layers, 2.5 wt % of linoleic acid, 0.9 wt % of Irga™ 819, 0.5 wt % of Irganox™ 1010, 5 wt % TiO₂ and monomer mixture of LA:HDDA, when LA:HDDA ratio by weight is 8:2.

### Working Example 3

Ink comprised of 50 wt % of InP based green QDs having ZnSe/ZnS double shell layers, 2.5 wt % of linoleic acid, 0.5 wt % of Irga™ 819, 2 wt % of Irganox™ 1010, 5 wt % TiO₂ and monomer mixture of LA:HDDA, when LA:HDDA ratio is by weight is 8:2.

### Comparative Example 4

Ink comprised of 50 wt % of InP based green QDs having ZnSe/ZnS double shell layers, 2.5 wt % of linoleic acid, 1 wt % of Irga™ 819, 0.5 wt % of Irganox™ 1010 and monomer mixture of LA:HDDA, when LA:HDDA ratio by weight is 75:25.

### Working Example 4

Ink comprised of 50 wt % of InP based green QDs having ZnSe/ZnS double shell layers, 2.5 wt % of linoleic acid, 0.5 wt % of Irga™ 819, 2 wt % of Irganox™ 1010 and monomer mixture of LA:HDDA, when LA:HDDA ratio by weight is 75:25.

### Comparative Example 5

Ink comprised of 40 wt % of InP based red QDs having ZnSe/ZnS double shell layers, 5 wt % of mPEG350-SH, 1 wt % of Irga™ 819, 0.5 wt % of Irganox™ 1010 and monomer mixture of LA:HDDA, when LA:HDDA ratio by weight is 8:2.

### Working Example 5

Ink comprised of 40 wt % of InP based red QDs having ZnSe/ZnS double shell layers, 5 wt % of mPEG350-SH, 0.5 wt % of Irga™ 819, 2 wt % of Irganox™ 1010 and monomer mixture of LA:HDDA, when LA:HDDA ratio by weight is 8:2.

### Working Example 6

Ink comprised of 40 wt % of InP based red QDs having ZnSe/ZnS double shell layers, 5 wt % of linoleic acid, 0.5 wt % of Irga™ 819, 1.5 wt % of Irganox™ 1010 and monomer mixture of LA:HDDA, when LA:HDDA ratio by weight is 8:2.

### Working Example 7: Test Cell Fabrication and EQE Measurement

QD ink obtained in working example 1 is injected into same two test cells with 10 μm gap to obtain two test cells of W.E. 1.

QD ink obtained in working examples 2 to 3 and comparative examples are each independently injected into test cells with 10 μm gap to obtain the test cells W.E.2 to 3 (n=2) and the test cells of C.E. 1 to 3 (n=2).

Then the obtained 6 test cells of W.E. 1 to 3 and C.E. 1 to 3 are cured by applying UV light irradiation with the following conditions to make a cured ink in the test cell.
UV intensity: 300 mW/cm²
Light source: 395 nm LED (peak light wavelength: 395 nm)
Under Ar condition
Curing Time: 10 sec.

In the same manner as described above, the obtained other 6 test cells of W.E. 1 to 3 and C.E. 1 to 3 are cured by applying UV light irradiation with the following conditions to make a cured ink in the test cell.
UV intensity: 2.3 mW/cm²
Light source: 395 nm LED (peak light wavelength: 395 nm)
Under Ar condition
Curing Time: 10 min.

EQE measurement is carried out by using integrating sphere equipped with excitation light by optical fiber (CWL: 450 nm) and spectrometer (Compass X, BWTEK). To detect the photons of the excitation light, air is used as a reference at room temperature.

The number of photons of light emission from the test cell towards the integrating sphere is counted by the spectrometer at room temperature. EQE is calculated by the following calculation Method.

EQE=Photons [Emission light]/Photons [Excitation light]

### Wavelength Range for Calculation

Excitation: 390 nm-490 nm
Emission: [Green] 490-600 nm
Emission: [Red] 580 nm-780 nm

Following table 1 show the results of the measurements.

TABLE 1

| | | | | EQE, % Film | EQE, % Film |
|---|---|---|---|---|---|
| | | | | cured 10 min | cured 10 sec |
| | AO | PI | AO:PI | at 2.3 mW/cm² | at 300 mW/cm² |
| Comparative | 0.5 | 1 | 0.5 | 32.1 | 32.1 |
| example 1 | | | | | |
| Working | 2 | 0.1 | 20 | 28.5 | 32.8 |
| example 1 | | | | | |
| Comparative | 0.5 | 1 | 0.5 | 33.9 | 32.8 |
| example 2 | | | | | |
| Working | 2 | 0.1 | 20 | 32.3 | 33.4 |
| example 2 | | | | | |
| Comparative | 0.5 | 0.9 | 0.55 | 34.1 | 33.2 |
| example 3 | | | | | |
| Working | 2 | 0.5 | 4 | 33.9 | 34.1 |
| example 3 | | | | | |

1.-15. (canceled)

16. A composition comprising at least;
i) a reactive monomer;
ii) a light emitting moiety;
iii) an antioxidant; and
iv) a polymerization initiator.

17. The composition of claim 16, wherein the total amount of said antioxidant based on the total amount of the solid content of the composition is more than 1 wt %.

18. The composition of claim 16, wherein the total amount of said polymerization initiator based on the total amount of the solid content of the composition is less than 1 wt % and above 0 wt. %.

19. The composition of claim 16, wherein the ratio of the total amount of the antioxidant to the total amount of the polymerization initiator is more than 1 and 100 or less.

20. The composition of claim 16, wherein said antioxidant is selected from one or more members of the group consisting of hindered amines, phenol derivatives, quinone derivatives, thiols and unsaturated alkyls with conjugated double bonds.

21. The composition of claim 16, wherein said polymerization initiator is selected from one or more members of the group consisting of Diphenyl(2,4,6-trimethylbenzoyl) phosphine oxide, Ethyl(2,4,6-trimethylbenzoyl)phenylphosphinate, Bis(2,4,6-Trimethylbenzoyl)phenylphosphine oxide, 4,4′-Bis(dimethylamino) benzophenone, 4,4′-Bis(diethylamino) benzophenone, 4-(Dimethylamino)benzophenone, Diphenyl (2,4,6 trimethylbenzoyl) phosphine oxide, 2-Hydroxy-2-methylpropiophenone, thioxanthen-9-one, Camphorquinone, 1-Phenyl-1,2-propanedione, carbazoles such as 9-vinylcarbazole, 1,2-Octanedione 1-[4-(phenylthio)phenyl]-2 (o-benzoyloxime), Ethanone 1-[9-ethyl-6-(2-methylbenzoyl)-9H-carbaaol-3-yl]-1-(O-acetyloxime),oxime esters.

22. The composition of claim 16, wherein the reactive monomer is a (meth)acrylate monomer selected from a mono-(meth)acrylate monomer, a di-(meth)acrylate monomer or a tri-(meth)acrylate monomer.

23. The composition of claim 16, further comprising a (meth)acrylate monomer represented by following chemical formula (I) and/or a (meth)acrylate monomer represented by following chemical formula (III); 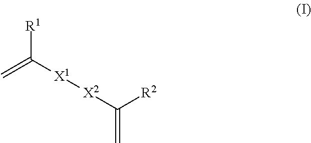
wherein
X¹ is a non-substituted or substituted alkyl group, aryl group or an alkoxy group or an ester group;
X² is a non-substituted or substituted alkyl group, aryl group or an alkoxy group or an ester group;
R¹ is a hydrogen atom, halogen atom of Cl, Br, or F, methyl group, alkyl group, aryl group, alkoxy group, ester group, or a carboxylic acid group;
R² is a hydrogen atom, halogen atom of Cl, Br, or F, methyl group, alkyl group, aryl group, alkoxy group, ester group, or a carboxylic acid group; 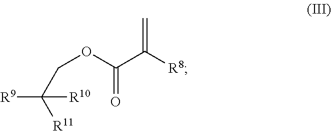
wherein R⁹ is hydrogen atom, a straight alkyl group having 1 to 25 carbon atoms or a (meth)acryl group represented by chemical formula (IV) 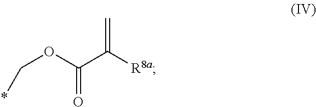
R¹⁰ is hydrogen atom, a straight alkyl group having 1 to 25 carbon atoms or a (meth)acryl group represented by chemical formula (V) 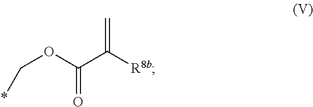
R¹¹ is hydrogen atom, a straight alkyl group having 1 to 25 carbon atoms or a (meth)acryl group represented by chemical formula (VI) 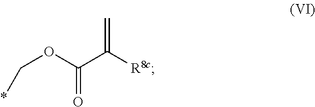
wherein R⁸, R^{8a}, R^{8b} and R^{8c} are, each independently or dependently of each other at each occurrence, H or CH₃;
wherein at least one of R⁹, R¹⁰ and R¹¹ is a (meth)acryl group, preferably two of R⁹, R¹⁰ and R¹¹ are a (meth)acryl group and other one is a hydrogen atom or a straight alkyl group having 1 to 25 carbon atoms.

24. The composition of claim 16, wherein the viscosity of the composition is 35 cP or less at room temperature.

25. The composition of claim 16, wherein the composition comprises a solvent 10 wt % or less based on the total amount of the composition.

26. A composition comprising a polymer derived from one or more of the reactive monomers of the composition of claim 16 and an antioxidant.

27. Process for fabricating the composition of claim 16 comprising at least the following step Y1;
Y1) mixing at least one light emitting moiety, a reactive monomer, an antioxidant and a polymerization initiator to form the composition.

28. A layer containing at least;
i) a (meth)acrylate polymer, obtained from the reactive monomers and the polymerization initiator in the composition of claim 16;
ii) a light emitting moiety; and
iii) an antioxidant.

29. Process of fabricating the layer of claim 28, wherein the process comprises at least the following steps;
I) providing the composition onto a substrate,
II) curing the composition.

30. A color conversion device comprising at least a 1^{st} pixel partly or fully filled with the layer of claim 28, and a bank comprising at least a polymer material.

31. An optical device containing at least one functional medium configured to modulate a light or configured to emit light, and the color conversion device of claim 30.
